(19) United States
(12) Patent Application Publication
(10) Pub. No.: US 2025/0388183 A1
(43) Pub. Date: Dec. 25, 2025

(54) BATTERY MANAGEMENT SYSTEM

(71) Applicant: ANTIGRAVITY BATTERIES LLC, Gardena, CA (US)

(72) Inventor: Scott Schafer, Gardena, CA (US)

(21) Appl. No.: 18/753,062

(22) Filed: Jun. 25, 2024

(51) Int. Cl. B60R 16/033; H01M 10/42; H02J 7/00

(52) U.S. Cl. CPC B60R 16/033; H01M 10/425; H02J 7/0063; H01M 2010/4271; H01M 2220/20

(57) ABSTRACT

A battery management system. The battery management system monitors an electrical energy level of a battery associated with a motor and compares the monitored electrical energy level to a minimum level of stored electrical energy required to start the motor. Upon determining that the battery's monitored electrical energy level is less than or equal to the minimum required level of stored electrical energy to start the motor, the system may place the battery into a hibernation mode such that it may be used to start the motor at a later date. The system includes a wireless communications module that the user may use via a mobile application running on a smart device to trigger the system to bring the battery out of hibernation and to use the battery to start the motor.

### FIELD OF THE INVENTION

This invention relates to battery management systems, including a battery management system that places the battery into a hibernation mode as necessary.

### BACKGROUND

Batteries are used to start motors (E.G., combustion vehicle motors) by providing electrical energy to a starter device that converts the electrical energy into mechanical energy that may be used to crank start the motor.

When such batteries are discharged to a certain level (E.G., due to an over discharging event such as having the vehicle lights left on for an extended period of time), the battery may no longer have the stored energy capacity to start the vehicle. In such cases, the battery may require a jump start, a quick charge, and/or may need to be replaced. This process is oftentimes very inconvenient, time consuming, and even dangerous. In fact, many vehicle owners do not have the proper knowledge or experience to perform such actions, and as such, require additional assistance (E.G., road-side assistance that may be expensive and time consuming).

Accordingly, there is a need for a battery management system that may determine an over discharging event of a battery and that may place the battery into a hibernation mode before the battery is completely discharged, E.G., while the battery still maintains enough stored energy to start the vehicle at a later date.

### BRIEF DESCRIPTION OF THE DRAWINGS

Other objects, features, and characteristics of the present invention as well as the methods of operation and functions of the related elements of structure, and the combination of parts and economies of manufacture, will become more apparent upon consideration of the following description and the appended claims with reference to the accompanying drawings, all of which form a part of this specification. None of the drawings are to scale unless specifically stated otherwise.

FIG. 1 shows an overview of a battery management system in accordance with exemplary embodiments hereof; and

FIG. 2 shows a workflow of a battery management system in accordance with exemplary embodiments hereof.

### DETAILED DESCRIPTION OF EXEMPLARY EMBODIMENTS

The current invention includes a battery management system that continually monitors a battery's operating parameters to ensure that the battery (E.G., a car battery) continues to have enough electrical energy stored within the battery's cells to start an associated motor and/or machine (E.G., a car) as needed. As will be described herein, the battery management system may determine to place the battery into a hibernation mode when the stored energy within the battery reaches a predetermined threshold. The battery management system also may include various communications capabilities to communicate the battery's operational parameters to a user (E.G., via Bluetooth to a user's smartphone), to notify the user that the battery has been placed in hibernation mode, and to enable the user to intentionally bring the battery out of hibernation mode so that the battery may be used (E.G., to start a car). The battery management system may include other functionalities as described herein.

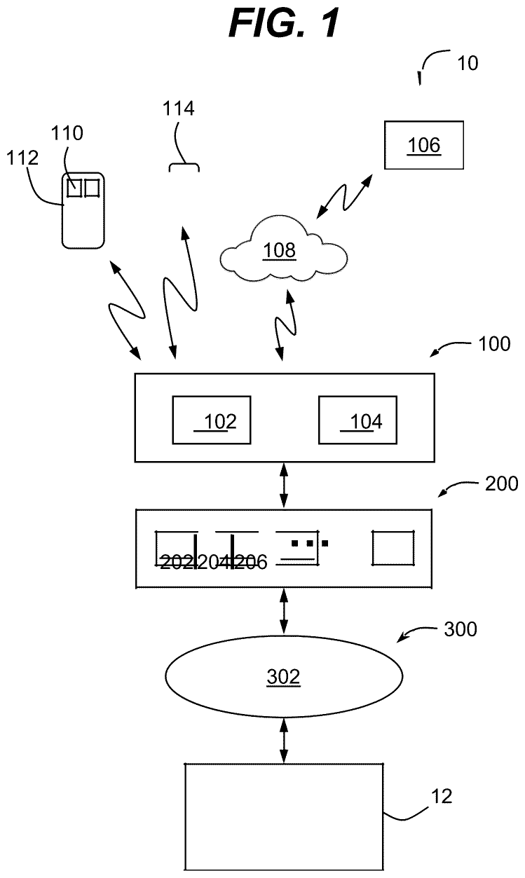

FIG. 1 shows a block diagram of a battery management system 10 (BMS 10) configured to monitor and generally manage the performance and various functionalities of a battery 12.

In some embodiments, as shown in FIG. 1, the battery management system 10 (also referred to herein as the system 10) includes a controller 100, a measurement system 200, and a hardware assembly 300. In general, the hardware assembly 300 provides physical connections (E.G., electrical connections) between the measurement system 200 and the battery 12. As described herein, the controller 100 controls the measurement system 200 to monitor one or more operating parameters and/or characteristics of the battery 12 via the hardware assembly 300 during the battery's operation. The controller 100 receives and analyzes the measurement information from the measurement system 200. If the controller 100 detects a problem with the battery 12, the controller 100 may manage and/or control the battery 12 accordingly. For example, if the battery 12 is a starting, light, and ignition (SLI) battery 12 designed to power the electrical systems of a vehicle, and if the controller 100 determines that the battery 12 is experiencing over-discharging, the controller 100 may determine an optimal condition to place the battery 12 into a hibernation mode such that the enough charge may remain in the battery 12 for jump starting the vehicle at a future date. The system 10 also may include other elements and/or may perform other activities as described herein.

In some embodiments, the battery management system 10 is designed to manage any type of battery 12, including without limitation, lithium batteries (E.G., Lithium Iron Phosphate, Lithium Sodium, and other types of Lithium batteries). Other battery chemistries also may be supported by the system 10. In some embodiments, the battery 12 may include one or more battery packs each including one or more cells. The supported batteries 12 may include starting, lighting, and ignition (SLI) batteries used in combustion engine vehicles (E.G., cars, trucks, motorcycles, boats, tractors, heavy equipment, farm equipment, and/or other types of vehicles). The supported batteries 12 also may include batteries used with generators, compressors, pumps, and/or other types of equipment. The supported batteries 12 also may include batteries used with electric vehicles (EV) such as the primary battery, the secondary battery (typically used for computer backup), other batteries, and any combinations thereof.

For the purposes of this specification, the battery management system 10 will be described primarily with respect to its use with batteries 12 associated with combustion engine vehicles such as cars. However, it is understood that this is for demonstration and that the system 10 may be used with any battery 12 that may benefit from its functionalities. It also is understood that the scope of the system 10 is not limited in any way by the type of batteries 12 that it may be used with.

In some embodiments, the system 10, E.G., the controller 100 and the measurement system 200, is contained within a housing that may be installed onto and/or otherwise integrated with the battery 12 using the hardware assembly 300. The hardware assembly 300 may include electrical connectors, electrical lines (E.G., cables, wires, etc.), and/or other connection mechanisms.

In some embodiments, the controller 100 includes a processor (E.G., a CPU, a microprocessor, a microcontroller, etc.), memory, supporting chipsets and circuitry, and/or other elements as required. The controller 100 also may include software 102 to perform the functionalities as required by the system 10 as well as operating systems, firmware, and other software as needed. The software 102 may include software drivers to interface with the measurement system 200, as well as analysis software to analyze the measurement data. The software 102 also may be used to control and manage one or more functionalities of the battery 12 as described herein (E.G., battery cell balancing, etc.).

In some embodiments, the controller 100 also includes a communication module 104 equipped with wireless communication modules such as, but not limited to, Bluetooth, Wi-Fi, cellular, satellite, radio frequency (RF), micro- and/or millimeter wave, Internet, LAN, WAN, infrared, other types of communication modules implementing other communication protocols, and/or any combinations thereof.

In some embodiments, as shown in FIG. 1, the system 10 also may include a cloud platform 106 (also referred to as a cloud server, backend system, backend, or controller) accessible through a network 108 such as the Internet, LAN, WAN, wireless communication systems, cellular communication systems, telephony or other types of communication systems or protocols. The backend system 106 preferably includes one or more servers with one or more software systems including one or more applications and one or more databases. The one or more software systems may include operating systems, system software, web server software, social networking software, communication software, software applications, scripts, firmware, other types of software systems, and any combinations thereof.

In some embodiments, the system 10 may be accessed and/or controlled by one or more users Un (E.G., via the network 102, Bluetooth, cellular, Wi-Fi, radio frequency (RF), micro- and/or millimeter wave, satellite communications, infrared, etc.) using one or more applications 110 (E.G., a mobile application or “app”, a browser, and/or other type(s) of applications) running on one or more computing devices 112 (E.G., client devices such as smart phones, tablet computers, smart watches, laptop computers, desktop computers, mobile media players, etc.). The system 10 also may be accessed and/or controlled by a user using a dedicated remote-control unit 114 (E.G., a fob) using Bluetooth, radio frequency (RF), micro- and/or millimeter wave, cellular, satellite, Wi-Fi, infrared, etc. This will be described in detail in other sections.

In some embodiments, as shown in FIG. 1, the measurement system 200 includes a voltage measurement module 202 designed to measure voltage, a current measurement module 204 designed to measure current, a temperature measurement module 206 designed to measure temperature, and/or other type(s) of measurement modules.

In some embodiments, as shown in FIG. 1, the hardware assembly 300 includes one or more electrical lines 302 (E.G., electrical cables, electrical wires, etc.), one or more electrical connectors 304, and other electrical connection elements. In some embodiments, the electrical lines 302 are configured to electrically connect the various modules of the measurement system 200 to the battery 12 in order to measure the operating parameters of the battery 12.

It is understood that the electrical arrangement between the system 10 and the battery 12 may include a centralized architecture (wherein all of the battery packs are connected to the system 10 directly), a modular topology, a primary/subordinate topology, a distributed topology, and/or other types of suitable configurations.

In some embodiments, the controller 100 controls the voltage measurement module 202 to measure one or more voltages of one or more of the battery pack's cells, the current measurement module 204 to measure one or more currents of one or more of the battery pack's cells, and/or the temperature measurement module 206 to measure one or more temperatures of one or more of the battery pack's cells. The resulting measurement data is then communicated to the controller 100 and used to calculate one or more battery parameters.

In some embodiments, the measured and/or calculated battery parameters may include:
1. Voltage (E.G., minimum, and/or maximum cell voltages, real time, historical (E.G., prior 30 days), etc.).
2. Current level being drawn in real time;
3. State of charge (SoC) or depth of discharge (DoD) (E.G., the speed of discharge in real time and over time (E.G., over days, weeks, etc.));
4. State of health (SoH) (remaining capacity of the battery as a fraction of the original capacity);
5. State of power (SoP) (the amount of power available for a defined time interval given the current power usage, temperature, and other conditions);
6. State of safety (SOS);
7. Maximum charge current as a charge current limit (CCL);
8. Maximum discharge current as a discharge current limit (DCL);
9. Energy delivered since last charge or charge cycle;
10. Internal impedance of each cell (to determine open circuit voltage);
11. Charge delivered or stored (also referred to as coulomb counting);
12. Total operating time since first use;
13. Total number of cycles;
14. Temperature of each battery pack (internal and external);
15. Coolant flow for air or liquid cooled batteries;
16. Cranking voltage drop upon starting of engine;
17. Voltage sag upon engine starting and corresponding required current;
18. Energy required to start the vehicle;
19. Run time remaining for given current load;
20. Batter cell balancing and status thereof (E.G., perform cell balancing); and
21. Other parameters.

In some embodiments, the controller 100 may make available at least some of the measurement data and/or at least some of the calculated battery parameters to the user of the system 10 via the controller 100, E.G., via the mobile application 110 in communication with the controller 100 and running on a user's electronic device 112 (E.G., cell phone, tablet computer, laptop computer, desktop computer, etc.).

In addition, in some embodiments, the controller 100 (E.G., via the mobile application 110) may alert the user of any problems occurring with the battery 12 in real time (E.G., if the battery 12 is being discharged at a high rate, if the voltage and current draws are too high, etc.).

As is known, a battery stores electrical energy. In addition, when a battery is used to start a vehicle (E.G., a car battery configured with an associated car's engine) the battery provides an electrical voltage and current to the car's starter which converts the electrical energy provided by the battery into mechanical energy. This mechanical energy is then used to crank the starter to start the car's engine. After the engine starts, the car's alternator produces an electric current that replaces the energy the starter drew from the battery. Given the above, in order to start a car using the car battery, the car battery must have enough stored electrical energy to crank the starter to start the car. If the battery does not have sufficient stored electrical energy (E.G., due to an over discharge caused by, E.G., leaving the headlights on), it may not be able to start the car and the battery may be referred to as “dead”. When this happens, the car may require a jumpstart to provide the needed electrical energy, or a replacement battery to provide the energy to start the car.

To avoid such a circumstance, in some embodiments, the system 10 may continually monitor the pertinent battery parameters described herein to determine a real-time health status of the battery 12. In some embodiments, the system 10 specifically monitors battery parameters that may indicate that the battery 12 is being over discharged and may soon not include enough stored energy to start the car if needed to do so.

In some embodiments, the system 10 measures and/or calculates, on a continual basis, how much electrical energy is required to start the particular car associated with the particular battery. That is, each time the car is started using the battery 12, the system 10 may measure and/or calculate the amount of energy that the battery 12 provided for the car to start. The system 10 also may measure and/or calculate other parameters that may influence how much energy is required to start the car, E.G., how much time has lapsed since the car was last started, the internal and/or external temperature of the battery 12 at the time of starting the car, etc. The system 10 may store this data in the controller 100 along with pertinent supplementary data associated with the parameter such as a date and time stamp. In this way, the controller 100 may save this data over time in order to build a data base of historical data regarding these and other parameters.

In some embodiments, using the data described above, the system 10 may determine a minimum amount of energy that the battery 12 must have stored (and therefore be able to provide to the car starter) in order to start the car engine. In some embodiments, the system 10 may determine the minimum amount of energy E_{M} that the battery 12 must have stored in order to start the car engine a particular number of times N (E.G., 5 times) over a particular period of time T (E.G., over the next 60 days).

In some embodiments, as the system 10 continues to monitor the status of the battery 12, if the system 10 determines that the amount of stored energy within the battery 12 (E.G., due to overcharging of the battery 12) is equal to the minimum amount of energy E_{M} required to start the car engine the number of times N over the particular period of time T, the system 10 may place the battery 12 into a hibernation mode.

In some embodiments, hibernation mode may set the battery 12 into a low quiescent current draw state by electrically disconnecting energy drawing loads from the battery 12. These loads may include all or some elements of the vehicle (E.G., the lights that were left on may be disconnected to remove the draw), as well as elements of the controller 100 and of the measurement system 200. In some embodiments, the low quiescent current draw of the battery 12 while in hibernation mode also may be taken into consideration during the calculation of the minimum amount of energy E_{M} required to start the car engine the number of times N over the particular period of time T. Furthermore, if the system 10 is to communicate with the user wirelessly (E.G., via a Bluetooth connection with the user's device 112 and mobile application 110) while the battery 12 is in hibernation mode (E.G., to initiate a battery wake-up as described below), the system 10 also may take into consideration the amount of energy required for the Bluetooth communication when calculating E_{M}.

Once in hibernation mode, the battery 12 may not be used until the user of the system 10 initiates a wake-up (E.G., an emergency start) of the battery 12. Once the wake-up is initiated, the minimum amount of energy E_{M} stored within the battery 12 may be used to start the vehicle.

In some embodiments, the system 10 includes a wireless wake-up functionality that enables the user to initiate the wake-up of the battery 12 wirelessly and without physically interacting with the battery 12 or with the vehicle. In some embodiments, the user may initiate the wireless wake-up of the battery 12 using the mobile application 110 running on an electronic device 112 (E.G., on the user's smartphone). In some embodiments, the electronic device 112 and/or the mobile application 110 may interface with the system 10 using Bluetooth communications protocols. In this case, the user may initiate the wake-up on the mobile application 110 by simply running the mobile application 110 on his/her device 112 and instructing the mobile application 110 (E.G., via the device's touchscreen or other control mechanisms) to send the wake-up command(s) to the system 10 via Bluetooth. Upon receiving the Bluetooth command signal, the system 10 may electrically connect the battery 12 to the electrical system of the vehicle (E.G., to the car's starter) such that the battery 12 may provide the required energy to crank the starter and start the car. The battery 12 may have this amount of energy available for use because of the fact it was placed into hibernation mode while still having the minimum amount of energy E_{M} required to start the car engine the number of times N over the particular period of time T.

In some embodiments, once the system 10 has brought the battery out of hibernation mode and has electrically connected the battery 12 with the car's starter, the mobile application 110 may instruct the user to start the car in the standard fashion, E.G., by using his/her ignition key. In this case, the battery 12 may provide its available stored electrical energy to the starter and the car may be started.

In addition, it is understood that if the electronic device 112 (E.G., the user's smartphone) is capable of utilizing other wireless communication protocols (E.G., radio frequency (RF), micro- and/or millimeter wave, satellite, infrared, etc.), and because the system 10 also may be designed to communicate with the device 112 using such communication protocols, the device 112 may communicate the wake-up command using any such technologies.

In some embodiments, the user may use a dedicated remote-control unit 114 (E.G., a fob) to initiate the wake-up of the battery 12 via the system 10. For example, in some embodiments, the remote-control unit 114 may interface with the system 10 via Bluetooth, cellular, Wi-Fi, radio frequency (RF), micro- and/or millimeter wave, satellite, infrared, by using other wireless communication protocols, and/or by using any combinations of the above. The remote-control unit 114 may include one or more control mechanisms (E.G., a button) that when activated may send the wake-up command to the system 10. The system 10 may then electrically connect the battery 12 to the car's starter such that the user may start the car in the traditional manner.

In some embodiments, the system 10 (E.G., the controller 100), may include an access point (E.G., located on the top or cap of the battery 12) that the user may easily access (E.G., by opening the hood of the car) and that may include a control mechanism (E.G., a physical button) that when activated (E.G., pressed) may command the system 10 to wake-up the battery 12. Once the user activates the control mechanism, the system 10 may electrically connect the battery 12 to the car's starter such that the user may start the car in the traditional manner. This method may be beneficial if the user's device 112 and/or remote-control 114 is unavailable, out of charge, etc.

In some embodiments, the user may electrically connect an external charging unit to the battery 12 and/or to the system 10 to initiate the battery wake-up. In this case, when the external charging unit is connected to the battery 12 and/or to the system 10, the system 10 may recognize the available charge from the charging unit and may electrically connect the charging unit to the battery 12 such that the battery 12 may receive a charge from the charging unit. The system 10 also may electrically connect the battery 12 to the car's starter such that the available charge from the charging unit may be used to start the car in the traditional manner.

In some embodiments, the user may initiate the battery wake-up by electrically connecting an external battery in parallel with the battery's electrical terminals. The system 10 may recognize the available charge from the external battery and may electrically connect the external battery to the battery 12 such that the battery 12 may receive a charge from the external battery. The system 10 also may electrically connect the battery 12 to the car's starter such that the available charge from the external battery may be used to start the car in the traditional manner.

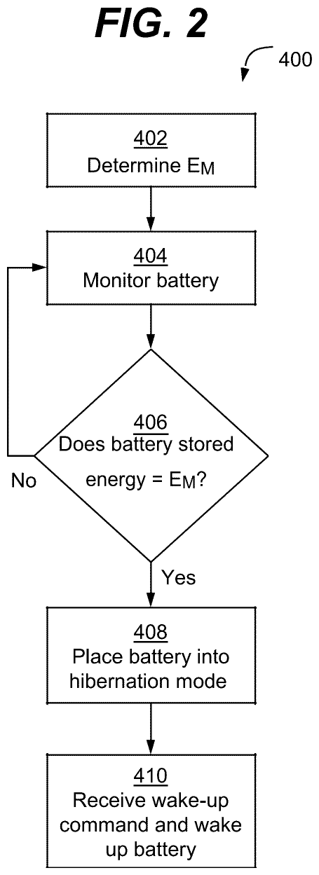

The above-described actions 400 are shown in FIG. 2 and are summarized below:

At 402 the system 10 may measure and/or calculate the minimum amount of energy E_{M} that the battery 12 must have stored and thereby be able to provide in order to start the car engine a particular number of times N over a particular period of time T.

At 404, the system 10 may continually monitor the amount of stored energy that the battery may have available to provide at any moment in time.

At 406, the system 10 may continually compare the real time amount of stored energy available from the battery 12 (from 404) with the minimum amount of energy E_{M} determined in 402.

When the amount of stored energy available from the battery 12 reaches the minimum amount of energy E_{M} required, the system may place the battery 12 into a hibernation mode (at 408). The battery 12 may preferably remain in hibernation mode until the user intentionally initiates the battery wake-up.

At 410, the system 10 may receive a wake-up command initiated by the user, E.G., via the mobile application 110 running on the user's device 112 via Bluetooth or other communications protocols. Once the wake-up has been initiated, the system 10 may place the battery 12 in electrical communication with the car's starter so that the battery 12 may be used to start the car in the traditional manner (E.G., using an ignition key).

### Additional Information

To begin use of the battery management system 10, the user may first install the system 10 with the battery 12. The user may then run the mobile application 110 on his/her smartphone 112 and pair the device 112 with the system 10 (E.G., via Bluetooth). The user may then enter information regarding the battery such as the battery name, date, amp hours of the battery, size of the associated car motor, and/or other information.

In some embodiments, once electrically configured with battery 12 and paired with the mobile application 110 and electronic device 112, the system 10 may begin monitoring the battery's parameters as described herein. In some embodiments, as the system 10 collects information regarding the battery, the system 10 (E.G., the controller 100) may communicate at least some of the following information to the user: name of battery, input capacity of battery, temperature of the battery, balance levels of the battery's cells, the battery's state of charge, the remaining run time at the current load level, the battery's real time voltage, the battery's real time load current (E.G., in watts, amps, etc.), the battery cell's internal resistance, number of cycles used by the battery (E.G., to see the life cycles used), voltage difference(s) between battery cells, history of capacity, voltage, current, temperature, and/or other parameters and/or other information.

While monitoring the battery voltage levels, the system 10 may measure the voltage levels over time and the speed of any decreasing voltage to determine accuracy of discharge.

When monitoring battery discharge load levels, the system 10 may evaluate the speed of discharge in relation to the level of the current load over time to determine when the maximum discharge may occur.

When monitoring battery temperature, the system 10 may monitor the effect the temperature may have on the battery to ensure that in colder weather where capacity may be decreased the battery may still retain enough electrical energy to restart the vehicle.

When monitoring battery capacity, the system 10 may calculate the capacity in amp hours such that the system 10 may determine the battery's capable output current compared to larger amp hour batteries that can change the required capacity level need to restart the vehicle.

It is understood that any aspect or element of any embodiment of the system 10 and method described herein or otherwise may be combined with any other aspect or element of any other embodiment of the system 10 and method to form additional embodiments of the system 10 and method, all of which are within the scope of the system 10 and method.

Where a process is described herein, those of ordinary skill in the art will appreciate that the process may operate without any user intervention. In another embodiment, the process includes some human intervention (E.G., a step is performed by or with the assistance of a human).

As used in this description, the term “portion” means some or all. So, for example, “A portion of X” may include some of “X” or all of “X”. In the context of a conversation, the term “portion” means some or all of the conversation.

As used herein, including in the claims, the phrase “at least some” means “one or more,” and includes the case of only one. Thus, E.G., the phrase “at least some ABCs” means “one or more ABCs,” and includes the case of only one ABC.

As used herein, including in the claims, the phrase “based on” means “based in part on” or “based, at least in part, on,” and is not exclusive. Thus, E.G., the phrase “based on factor X” means “based in part on factor X” or “based, at least in part, on factor X.” Unless specifically stated by use of the word “only,” the phrase “based on X” does not mean “based only on X.”

As used herein, including in the claims, the phrase “using” means “using at least,” and is not exclusive. Thus, E.G., the phrase “using X” means “using at least X.” Unless specifically stated by use of the word “only”, the phrase “using X” does not mean “using only X.”

In general, as used herein, including in the claims, unless the word “only” is specifically used in a phrase, it should not be read into that phrase.

As used herein, including in the claims, the phrase “distinct” means “at least partially distinct.” Unless specifically stated, distinct does not mean fully distinct. Thus, E.G., the phrase, “X is distinct from Y” means that “X is at least partially distinct from Y,” and does not mean that “X is fully distinct from Y.” Thus, as used herein, including in the claims, the phrase “X is distinct from Y” means that X differs from Y in at least some way.

As used herein, including in the claims, a list may include only one item, and, unless otherwise stated, a list of multiple items need not be ordered in any particular manner. A list may include duplicate items. For example, as used herein, the phrase “a list of XYZs” may include one or more “XYZs”.

It should be appreciated that the words “first” and “second” in the description and claims are used to distinguish or identify, and not to show a serial or numerical limitation. Similarly, the use of letter or numerical labels (such as “(a)”, “(b)”, and the like) are used to help distinguish and/or identify, and not to show any serial or numerical limitation or ordering.

No ordering is implied by any of the labeled boxes in any of the flow diagrams unless specifically shown and stated. When disconnected boxes are shown in a diagram, the activities associated with those boxes may be performed in any order, including fully or partially in parallel.

While the invention has been described in connection with what is presently considered to be the most practical and preferred embodiments, it is to be understood that the invention is not to be limited to the disclosed embodiments, but on the contrary, is intended to cover various modifications and equivalent arrangements included within the spirit and scope of the appended claims.

1. A method of managing a battery:
(A) measuring a stored electrical energy level of the battery;
(B) storing the measured stored electrical energy level in memory;
(C) determining a minimum amount of stored electrical energy required to start a motor associated with the battery a single time;
(D) based at least in part on the minimum amount of stored electrical energy required to start the motor associated with the battery a single time, determining a minimum amount of stored electrical energy required to start the motor two or more times;
(D) determining if the stored electrical energy level in memory is equal to or less than the minimum amount of stored electrical energy required to start the motor associated with the battery two or more times;
(E) upon a determination that the stored electrical energy level in memory is equal to or less than the minimum amount of stored electrical energy required to start the motor associated with the battery two or more times, then:
(F) placing the battery into a hibernation mode;
(G) receiving a wireless communication from a user of the battery to take the battery out of the hibernation mode; and
(H) taking the battery out of the hibernation mode.

2. The method of claim 1 wherein the wireless communication is a Bluetooth communication.

3. The method of claim 2 wherein the Bluetooth communication is initiated from an electronic device associated with the user.

4. The method of claim 3 wherein the electronic device is a smart device running at least one mobile application that implements the Bluetooth communication.

5. The method of claim 1 wherein when the battery is placed into the hibernation mode, the battery is electrically disconnected from at least one current drawing load.

6. The method of claim 5 wherein the at least one current drawing load includes one or more current drawing loads associated with the motor associated with the battery.

7. The method of claim 5 wherein the at least one current drawing load include one or more current drawing load associated battery management system.

8. The method of claim 1 further comprising:
(I) electrically configuring the battery with the motor;
(J) using the battery to start the motor.

9. The method of claim 1 wherein the minimum amount of stored electrical energy required to start the motor associated with the battery includes a minimum amount of stored electrical energy required to start the motor at least one or more times over a predefined period of time.

10. (canceled)

11. The method of claim 9 wherein the predefined period of time includes at least sixty days.

12. A system for managing a battery comprising:
a controller including a wireless communication module;
an electrical measurement system electrically configured with the battery and in communication with the controller;
the controller adapted to:
measure, using the electrical measurement system, a stored electrical energy level of the battery;
storing the measured stored electrical energy level in memory;
determine a minimum amount of stored electrical energy required to start a motor associated with the battery a single time;
based at least in part on the minimum amount of stored electrical energy required to start the motor associated with the battery a single time, determining a minimum amount of stored electrical energy required to start the motor two or more times;
determine if the stored electrical energy level in memory is equal to or less than the determined minimum amount of stored electrical energy required to start the motor associated with the battery two or more times;
upon a determination that the stored electrical energy level in memory is equal to or less than the minimum amount of stored electrical energy required to start the motor associated with the battery two or more times, then:
place the battery into a hibernation mode;
receive, by the wireless communication module, a wireless communication from a user of the battery to take the battery out of the hibernation mode; and
take the battery out of the hibernation mode.

13. The system of claim 12 wherein the wireless communication is a Bluetooth communication.

14. The system of claim 13 wherein the Bluetooth communication is initiated from an electronic device associated with the user.

15. The system of claim 14 wherein the electronic device is a smart device running at least one mobile application that implements the Bluetooth communication.

16. The system of claim 12 wherein when the battery is placed into the hibernation mode, the battery is electrically disconnected form at least one current drawing load.

17. The system of claim 16 wherein the at least one current drawing load includes one or more current drawing loads associated with the motor and/or at least one current drawing load includes one or more current drawing loads associated battery management system.

18. (canceled)

19. The system of claim 12 wherein the controller is further adapted to:
electrically configure the battery with the motor;
use the battery to start the motor.

20. The system of claim 12 wherein the minimum amount of stored electrical energy required to start the motor associated with the battery includes a minimum amount of stored electrical energy required to start the motor at least two times over a predefined period of time.

21. A system for managing a battery comprising:
a controller including a wireless communication module;
an electrical measurement system electrically configured with the battery and in communication with the controller;
the controller adapted to:
measure, using the electrical measurement system, a stored electrical energy level of the battery;
storing the measured stored electrical energy level in memory;
determine a minimum amount of stored electrical energy required to start a motor associated with the battery a single time over a predefined period of time;
based at least in part on the minimum amount of stored electrical energy required to start the motor associated with the battery a single time, determining a minimum amount of stored electrical energy required to start the motor two or more times;
determine if the stored electrical energy level in memory is equal to or less than the determined minimum amount of stored electrical energy required to start the motor associated with the battery two or more times over a predefined period of time;
upon a determination that the stored electrical energy level in memory is equal to or less than the minimum amount of stored electrical energy required to start the motor associated with the battery two or more times over a predefined period of time, then:
place the battery into a hibernation mode;
receive, by the wireless communication module, a wireless communication from a user of the battery to take the battery out of the hibernation mode; and
take the battery out of the hibernation mode.

22. The method of claim 21 wherein the predefined period of time includes at least sixty days.
